(19) United States
(12) Patent Application Publication
(10) Pub. No.: US 2008/0052903 A1
(43) Pub. Date: Mar. 6, 2008

(54) Method of Forming Aluminum Based Alloy Wiring Circuit and Method of Forming Element Structure of Display Device

(76) Inventors: Yoshinori Matsuura, Ageo-shi (JP); Takashi Kubota, Ageo-shi (JP)

Correspondence Address: ROBERTS & ROBERTS, LLP;ATTORNEYS AT LAW, P.O. BOX 484, PRINCETON, NJ, 08542-0484, US

(21) Appl. No.: 11/847,423

(22) Filed: Aug. 30, 2007

(30) Foreign Application Priority Data
Aug. 31, 2006 (JP) P2006-236826

(51) Int. Cl. H05K 3/20; C22C 21/00; H01B 13/00

(52) U.S. Cl. 29/831; 216/16; 420/528

(57) ABSTRACT

The present invention proposes the technique in which aluminum based alloy is used as a wiring material, and the number of process is sharply reduced in the technique of forming the aluminum based alloy wiring circuit, thereby making it possible to efficiently manufacture the element. The present invention is a method of forming the wiring circuit by the aluminum based alloy, wherein the development process of a resist layer and the etching process of an aluminum based alloy film are simultaneously performed with a developing solution for the aluminum based alloy film laminated with the resist layer. This aluminum based alloy is preferably 5 Å/sec to 40 Å/sec in etching rate by the developing solution.

### BACKGROUND OF THE INVENTION

1. Field of the Invention

The present invention relates to a technique of manufacturing elements constituting a display device such as a liquid crystal display, and in particular, to a technique of forming an aluminum based alloy wiring circuit.

2. Description of the Related Art

In recent years, the development of a display device such as a liquid crystal display has been making a remarkable progress, and as a display device of this liquid crystal display, for example, an element using a thin film transistor (hereinafter, abbreviated to TFT) has been in heavy usage. As a wiring material constituting this TFT, an aluminum (hereinafter, abbreviated to Al as the case may be) based alloy is used.

When this aluminum based alloy is used as the wiring material, at present, the following wiring circuit formation is performed. First, by a sputtering method and the like, an Al based alloy film is formed (1) on a substrate, and the Al based alloy film is coated (2) with a resist, and after subjected to a pre-baking process (3), a circuit pattern film is disposed and an exposure is performed (4), and development (5) and a cleaning process (6) are performed. Thereafter, a post-baking process is performed (7), and an inspection of the resist etched for the circuit pattern formation is performed (8). Subsequently, an etching process of the Al based alloy film is performed (9) and a cleaning is performed (10), and a separation of the resist is performed (11), and a cleaning process (12) is performed again. By so doing, the wiring circuit is formed by the Al based alloy film, and a finishing state of the wiring circuit is checked (13) (see “Semiconductor Device-Basic Theory and Process Technique” by S. M. Gee, translated by Yasuo Nannichi, Mitsuo Kawabe, and Fumio Hasegawa, Second Edition, published by Sangyo Tosho).

The conventional method of forming the aluminum based alloy wiring circuit using this aluminum based alloy as a wiring material basically requires 13 processes when an inspection process is included. Thus, the requirement of many processes just for the formation of the aluminum based alloy wiring circuit leads to the hindrance of an efficient manufacture of the element such as the TFT, thereby inviting an increase in the manufacturing facility and the cost of manufacturing. Moreover, many factors for lowering the manufacturing yield of the element are brought about.

### SUMMARY OF THE INVENTION

The present invention has been carried out in view of the above described circumstances, and an object of the invention is to propose a technique in which an aluminum based alloy is used as a wiring material and the number of processes are reduced to a large extent in the technique of forming an aluminum based alloy wiring circuit, thereby enabling an efficient manufacture of the element.

To solve the above described problem, the present invention is a method of forming a wiring circuit by an aluminum based alloy, wherein the development process of a resist layer and the etching process of an aluminum based alloy film are simultaneously performed by a developing solution for the aluminum based alloy film laminated with a resist layer.

The aluminum based alloy of the present invention preferably has an etching rate by the developing solution in 5 Å/sec to 40 Å/sec.

Further, the aluminum based alloy of the present invention preferably includes nickel of 0.1 at % to 8.0 at %.

The aluminum based alloy of the present invention preferably includes boron of 0.05 at % to 1.0 at %.

Further, in the method of forming the aluminum based alloy wiring circuit according to the present invention, the developing solution is preferably a solution containing TMAH (tetramethylammonium hydroxide).

In the present invention, when a display device element having a direct adhering portion with the aluminum based alloy wiring circuit and a transparent electrode is to be formed, the method of forming the display device is taken as a method of forming an element structure of display device including, A: a deposition process of forming an aluminum based alloy film, B: an exposure process of disposing a resist layer on the aluminum based alloy film and performing an exposure process of a wiring pattern, C: a process of forming an aluminum based alloy wiring circuit to simultaneously perform a development process of a wiring circuit pattern of the resist layer by a developing solution and an etching process to form the aluminum based alloy wiring circuit, D: a separation process of removing the resist layer on the aluminum based alloy wiring circuit, and E: a adhering process of directly adhering the aluminum based alloy wiring circuit and a transparent electrode.

In the method of forming the element structure of display device of the present invention, F: a contact hole forming process of forming an insulating layer on the aluminum based alloy wiring circuit and forming a contact hole on the insulating layer, and G: an element structure forming process of forming the transparent electrode on the contact hole and directly adhering the aluminum based alloy wiring circuit and the transparent electrode inside the contact hole can be included.

In the method of forming the element structure of display device of the present invention, the transparent electrode is preferably a transparent conductive film containing any of In, Sn, and Zn.

The Al based alloy in the method of forming the element structure of display device of the present invention is preferably 5 Å/sec to 40 Å/sec in etching rate by a developing solution, and preferably includes nickel of 0.1 at % to 8.0 at %, and preferably includes boron of 0.05 at % to 1.0 at %.

In the deposition process in the method of forming the element structure of display device of the present invention, an aluminum based alloy target containing nickel of 0.1 at % to 8.0 at % is preferably used in the case of using the sputtering method.

Furthermore, the present invention relates to a display device element manufactured by the method of forming the element structure of display device of the present invention described above.

According to the present invention, the formation of the display device element such as the TFT can be efficiently manufactured. More specifically, when the wiring circuit is to be formed by the aluminum based alloy, the thirteen processes required heretofore can be reduced up to the eight processes, so that a manufacturing facility cost and a manufacturing cost of the element can be suppressed and the lowering of a manufacturing yield accompanied with the processes can be prevented.

### BRIEF DESCRIPTION OF THE DRAWING

FIG. 1 is a schematic perspective view of a test sample laminated with an ITO film and an Al based alloy film crossed with each other.

### DETAILED DESCRIPTION OF THE PREFERRED EMBODIMENTS

Hereinafter, an exemplary embodiment of the present invention will be described, however the present invention is not limited to the following embodiment.

Composition of Al Based Alloy:

An Al based alloy in the present invention is preferably 5 Å/sec to 40 Å/sec in etching rate by a developing solution. This is because, in the present invention, being etched by the developing solution, an Al based alloy film is preferably the Al based alloy dissolved at a predetermined etching speed for the developing solution. When this etching rate is less than 5 Å/sec, it takes an extremely long time to form the wiring circuit, and therefore, it is not practical. On the other hand, when the etching speed exceeds 40 Å/sec, a side etching of the wiring circuit is liable to proceed too far, and a control of the etching process becomes difficult. In the present invention, as the etching of the Al based alloy film is performed by the developing solution, as long as the Al based alloy is dissolvable by the developing solution, no particular limitation is imposed as to which developing solution is combined by which composition of the Al based alloy.

A dissolution phenomenon of the Al based alloy by the developing solution is such that a metal having an oxide reduction potential more precious than the oxide reduction potential of the Al is added to the Al, and when its polarized state is large, the developing solution plays a role of electrolytic solution, and a cell reaction is caused in the Al based alloy, and a dissolution of the Al based alloy occurs. That is, the larger the amount of the precious metal added to the Al is, the larger the etching rate (dissolution speed) toward the developing solution is likely. Further, since the developing solution usually is prone to easily dissolve the Al based alloy as the solution temperature becomes higher at the processing time, the applicable Al based alloy is preferably decided depending on the type of the developing solution and the solution conditions.

Further, the Al based alloy of the present invention preferably contains nickel (Ni) of 0.1 to 8.0 at %. When the Ni content is less than 0.1 at %, the etching rate in the developing solution becomes slow, and an etching removal of the Al based alloy film in the development/etching process is prone to be not sufficiently performed. When the Ni content is 0.1 at % or more, the Al based alloy wiring circuit can be formed through the etching with the developing solution, and when the Ni content is 0.5 at % or more, it is further preferable. This is because, when the Ni content is 0.5 at % or more, direct adhesion characteristics with the transparent electrode can be certainly secured. On the other hand, when the Ni content exceeds 8.0 at %, the Al based alloy film is removed in the development/etching process and cloudiness is prone to occur on the exposed glass substrate surface, and this is not preferable. The Al based alloy containing Ni becomes a precious electrode potential, and when contacting an alkali developing solution, a cell reaction of the Al based alloy itself occurs, and the progress of the etching of the Al based alloy is made easy. Containing Ni makes the direct adhesion characteristics with the transparent electrode good. Particularly, when the Ni content is 4.0 at % to 6.0 at %, the Al based alloy wiring combining a high heat resistance and a low resistivity can be formed, and this is preferable.

The Al based alloy in the present invention, when allowed to contain boron (B) of 0.05 to 1.0%, can make a direct adhesion with a semiconductor such as n⁺-Si. Particularly, when the B content is 0.2 at % to 0.8 at %, the Al based alloy wiring combining a high heat resistance and a low resistivity can be formed, and this is preferable, and further, a ternary based Al based alloy containing the above described Ni and B with the balance being the Al is most preferable. Incidentally, the Al based alloy of the present invention, as long as etchable by the developing solution, is not particularly limited in its composition, but the Al itself is preferably contained 75 at % or more.

Film Deposition Process of Al Based Alloy Film:

The deposition of the Al based alloy film of the present invention is not limited as long as it is a method in which the Al based alloy film can be formed on the substrate by a sputtering method, a CVD method, a printing method, and the like, and particularly, the sputtering method is preferable. For example, when the deposition is performed by the sputtering method, the conditions such as substrate superheated temperature room temperatures (30° C.) to 200° C., DC3 to 30 W/cm², sputtering pressures 0.25 to 0.6 Pa, and film thickness 500 to 5000 Å can be applied. Incidentally, in the Al based alloy film of the present invention, as far as the effect of the present invention can be exerted, the existence of unavoidable impure ingredients such as sputtering gas component mixed at the film deposition time is not prevented.

An Al based alloy target used when the deposition process is performed by the sputtering method can employ the one manufactured by mixing various types of metals into aluminum, and dissolving and casting them. Further, the Al based alloy target obtained by the manufacturing method such as a powder molding method, a spray forming method, and the like can also be used. The composition of the Al based alloy film is slightly swayed depending on the deposition conditions at the sputtering time, but the Al based alloy film of approximately the same composition as the target composition can be easily formed.

Resist Coating Process:

The resist used in the manufacture of the element such as the TFT can be applied, and for its coating conditions, the known coating conditions can be applied. Specifically, for example, the resist containing novolak resin is used, and it can be made into a resist thickness of 1.0 to 1.5 μm with a spin coater at 3000 rpm.

Pre-Baking Process:

This process can be performed by using a hot plate at temperatures 100 to 120° C. for 30 seconds to five minutes.

Exposure Process:

General exposure conditions, which are known in the manufacture of the element such as the TFT, can be applied Specifically, for example, an ultraviolet exposure amount can take a total accumulated exposure amount as 15 to 100 mJ/cm². For the mask to form a circuit pattern, a Cr photo mask can be used.

Development/Etching Process:

In the present invention, though there is no particular limit imposed on the developing solution, the one containing sodium hydrogenphosphate, m-sodium metasilicate, TMAH (tetramethylammonium hydroxide) and the like is preferable. Particularly, the TMAH is preferable. When the TMAH is used, the TMAH density of 2.0 to 3.0 wt % can be applied. As the temperature of the developing solution greatly affects the patterning property of the resist, the etching can be performed at 20 to 40° C. Hence, the etching rate of the Al based alloy also depends on the temperature of this developing solution. When the temperature of the developing solution is less than 20° C., the need arises to increase the exposure amount toward the resist, and this is not practical. On the other hand, when the solution temperature exceeds 40° C., the adjustment of the TMAH density becomes difficult, and the running characteristics of the developing solution are prone to become bad. The developing solution can perform the development/etching process by applying a paddle method, a DIP (dipping) method, a shower method, and the like. Particularly, the shower method is preferable. Though preferable if the shower pressure is much higher, the process can be performed at 0.2 to 1.0 MPa.

The process in this development/etching process may be performed until the development process of the resist layer and the etching process of the Al based alloy film by the developing solution are completed. In other words, the process by the developing solution may be performed until the development process of the resist layer is performed and the Al based alloy film exposed on the portion in which the resist layer is removed is etched by the developing solution, and the Al based alloy wiring circuit in a state having a resist layer on the upper portion is formed. Incidentally, in this development/etching process, when the development process of the resist layer alone is performed, the process becomes the same as the conventional method.

Resist Separation Process:

Although a separation solution of the resist is not particularly limited, any of a water-based separation solution and a non-water-based separation solution can be applied. The water-based separation solution comprises the solvent containing the water, and includes some solvents containing organic amines, glycol, and the like in the water. The non-water-based separation solution comprises the solution containing no water, and includes some solvents containing either or both of a polar solvent such as dimethylsulfoxide and acetone and organic amines such as alkanolamine and 2-aminoethanol. More preferable is a water-based separation solution. Still more preferable is a water-based separation solution containing glycol and organic amines, and the water-based separation solution containing the organic amines is most preferable. The conditions can be set at the solution temperatures of 40 to 80° C., and the separation time for one minute to 10 minutes. The method of the separation process can apply the DIP (dipping) method and the shower method, but the shower method is preferable.

Cleaning Process:

The cleaning process after the separation of the resist is applicable with a general cleaning condition known in the manufacture of the element such as the TFT. Specifically, for example, alcohol cleaning or ultra-pure water cleaning are applicable. The cleaning method includes the DIP (dipping) method and the shower method, but the shower method is preferable. The cleaning time can be set for one minute to ten minutes. The longer cleaning time can reliably remove the clouding of the glass substrate surface exposed by the etching of the Al based alloy film.

According to the present invention, when compared with the conventional method of forming the Al based alloy wiring circuit requiring 13 processes, the Al based alloy wiring can be formed by eight processes of (1) a deposition process of the Al based alloy film, (2) a resist coating process, (3) a pre-baking process, (4) an exposure process, (5) a development/etching process, (6) a resist separation process, (7) a cleaning process, and (8) an inspection.

In the method of forming the element structure of display device of the present invention, in addition to each of the above described process conditions, the following processes are provided.

Adhering Process of Transparent Electrode:

The transparent electrode directly adhered with the Al based alloy wiring circuit is preferably a transparent conductive film containing any of In, Sn, and Zn. A transparent electrode film such as so-called ITO (Indium Tin Oxide) or IZO (Indium Zinc Oxide) is applicable. As the deposition conditions of the transparent electrode, in the case of the ITO, when an ITO target (composition: In₂O₃—10 wt % SnO₂) is used and the sputtering conditions are set such that the substrate temperatures are 200 to 300° C., an input power is 1.0 to 3.0 Watt/cm², an argon gas flow rate is 80 ccm, an oxygen gas flow rate is 1.5 to 3.1 ccm, and a pressure is 0.3 to 0.4 Pa, a crystallized ITO film can be formed. Further, when the conditions are set such that the substrate temperatures are 50 to 150° C., the input power is 1.0 to 3.0 Watt/cm², the oxygen gas flow rate is 0.3 to 1.1 ccm, and the pressure is 0.3 to 0.4 Pa, the amorphous (non-crystal) ITO film can be formed. When the deposition of the amorphous (non-crystal) ITO film is performed, an Ar gas may be added with H₂O, thereby performing the sputtering.

Formation of Insulating Layer:

An insulating layer can be made of SiNx, and its thickness can be set as 2000 Å to 5000 Å. This insulating layer can be formed by the sputtering method under the conditions that an input power RF is 1.5 to 6.2 Watt/cm², an argon gas flow rate is 60 to 200 ccm, a nitrogen gas flow rate is 5 to 10 ccm, a pressure is 0.3 to 0.6 Pa, and substrate temperatures are 200 to 400° C.

Process of Forming Contact Hole:

When a contact hole is to be formed in the insulating layer, a dry etching gas of CF₄ or SF₆ is preferably used. The contact hole forming conditions, in the case of the CF₄ gas, can be taken as a CF₄ gas flow rate 35 to 150 ccm, an oxygen gas flow rate 0 to 30 ccm, a pressure 2.0 to 10 Pa, and an output 75 to 200 W/φ200 mm, and in the case of the SF₆ gas, a SF₆ gas flow rate 25 to 125 ccm, an oxygen flow rate 0 to 30 ccm, a pressure 2.0 to 10 Pa, and an output 50 to 180 W/φ200 mm. By the above described separation solution, the resist is preferably removed.

According to the above described method of forming the element structure of display device of the present invention, the post-baking process of the resist and the etching process of the Al based alloy film only can be omitted, and therefore, as compared with the conventional manufacture, an efficient display device element can be manufactured. The method of forming the element structure of display device of the present invention is not applicable not only to the manufacture of the liquid crystal display, but to the manufacturing process of a so-called semiconductor element, a MEMS (Micro Electro Mechanical system), and the like.

### EXAMPLE 1

Hereinafter, examples of the present invention is described. In this Example 1, an Al based alloy film of each composition as shown in Table 1 was formed, thereby forming a wiring circuit of the predetermined pattern. Deposition conditions and forming conditions of the wiring circuit were set as follows.

First, a deposition of the Al based alloy film is described. The deposition was performed by a sputtering method. An Al based alloy target used at this time employed the one manufactured in which various metals were mixed in aluminum, and were dissolved and agitated in vacuum, and after that, were cast in an inactive gas atmosphere, and after that, the obtained ingot was milled and shaped, and the surface to be provided for sputter was plane-processed. The sputtering conditions were taken as a substrate heating temperature 50° C., an input DC power 1 kW (3.1 W/cm²), an argon gas flow rate 100 ccm, and an argon pressure 0.5 Pa, and by a magnetron sputtering apparatus (MSL-464: made by Tokki Corporation), an Al based alloy film of 2000 Å in thickness was formed on a glass substrate (#1737, a non-polished non-alkali glass of 0.7 mm in thickness: made by Corning Incorporated).

The Al based alloy film surface was covered by a resist (TFR-970: made by Tokyo Ohka Kogyo Co., Ltd./coating conditions: a spin coater of 3000 rpm and a resist thickness target after baking: 1.4 μm), and was subjected to a pre-baking process (hot plate at 110° C. for 1.5 minutes).

Further, a Cr mask pattern film to form a circuit pattern in wiring width of 10 μm, 20 μm, 50 μm, and 100 μm was used, and an exposure of 25 mJ/cm² was performed by ultraviolet rays.

After that, the developing solution (solution temperature 23° C.) of 2.38 wt % in TMAH density was used, and the development/etching process was performed at a shower pressure of 0.3 MPa for five minutes of the processing time.

Subsequently, by using a water-based separation solution (TST-AQ3: made by Tokyo Ohka Kogyo Co., Ltd.) containing organic amines comprising monoethanolamine, diethylhydroxyamine, other additives, and water, a resist separation process was performed at the solution temperature of 40° C. and a shower pressure of 0.3 MPa with the processing time taken as five minutes.

After the resist separation process, a cleaning (the shower presser of 0.3 MPa and the processing time of five minutes) was performed by isopropylalcohol solution, and further, the cleaning (the shower presser of 0.3 MPa and the processing time of five minutes) was performed by an ultrapure water.

A finishing state of the side etching characteristic (whether the etching was performed according to a desired wiring width) and the wiring circuit was confirmed for each wiring circuit formed as described above. Further, the ITO adhesion characteristic of each Al based alloy film was also checked. The detail of each estimation method will be described as follows.

Side Etching Characteristic:

The estimation of this characteristic was performed by measuring the wiring width of the formed Al based alloy wiring and the wiring of the Cr mask and comparing these line widths thus measured. The line width was measured by using a stylus profile meter (P-15: made by KLA Tencor Corporation). By comparing the wiring width value of the Al based alloy wiring and the wiring width value of the Cr mask, the wiring width value of the Al based alloy wiring within ±3% for the wiring width of the mask was estimated as ⊚, the one within ±6% was estimated as ◯, the one within ±10% was estimated as Δ, and the one otherwise was estimated as ×.

Finishing State of Wiring Circuit:

The finishing state of this wiring circuit was determined by a degree of cloudiness generated on the glass substrate surface observed by an optical microscope. The estimation was classified into four levels of no cloudiness (none), a thinly cloudy state confirmed (few), a cloudy state confirmed (moderate), and an extremely cloudy state (heavy). Incidentally, the confirmation of this finishing state of the wiring circuit was performed by observing the glass surface immediately after the development/etching process.

ITO Adhesion Property:

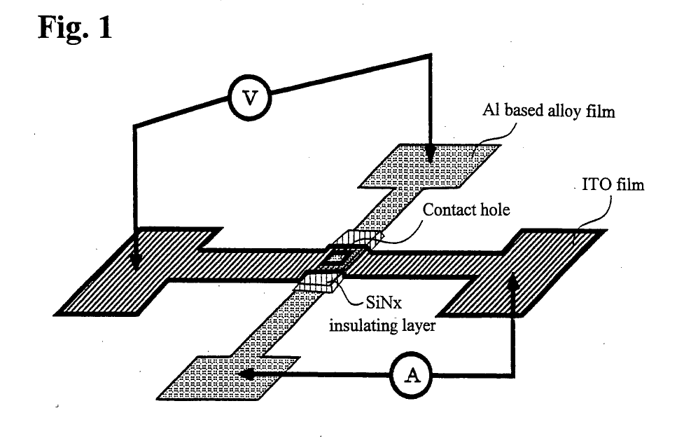

The ITO adhesion property, as shown in the schematic perspective view of FIG. 1, was estimated by forming an ITO (In₂O₃—10 wt % SnO₂) electrode layer (1000 Å in thickness and a circuit width of 10 μm) on the glass substrate, and by using a test sample (Kelvin element) formed so as to cross each composition film layer (2000 Å in thickness and the circuit width of 10 μm) on the electrode layer.

The preparation of this test sample, first, employed the Al based alloy target of each composition described in Table 1 on the glass substrate, and an Al based alloy film of 2000 Å in thickness was formed under the above described sputtering conditions. The substrate temperature of the sputtering time at this time was taken as 100° C. Each Al based alloy film surface was covered with a resist (TFR-970: made by Tokyo Ohka Kogyo Co., Ltd.), and was subjected to an exposure process by disposing a pattern film for 50 μm width circuit formation, and was subjected to a development/etching process by a TMAH solution of a density 2.38% and the solution temperature of 23° C. After that, the removal of the resist was performed by a water-based separation solution (TST-AQ3: made by Tokyo Ohka Kogyo Co., Ltd.) containing organic amines, thereby forming an Al based alloy wiring circuit of 50 μm in width.

A substrate on which the Al based alloy wiring circuit of 50 μm in width is formed was subjected to a pure water cleaning and a drying process, and its surface was formed with an insulating layer (4200 Å in thickness) of SiNx. The deposition of this insulating layer was performed by using the sputtering apparatus under the sputtering conditions of an input power RF 3.0 Watt/cm², an argon gas flow rate 90 sccm, a nitrogen gas flow rate 10 sccm, a pressure 0.5 Pa, and a substrate temperature 300° C.

Subsequently, the insulating layer surface was covered by a resist (TFR-970: made by Tokyo Ohka Kogyo Co., Ltd.), and was subjected to an exposure process by disposing a pattern film for the contact hole of 10 μm×10 μm square, and was subjected to a development process by a TMAH developing solution. By using a dry etching gas of CF₄, a contact hole was formed. The forming conditions of the contact hole ware taken as the CF₄ gas flow rate 50 sccm, an oxygen gas flow rate 5 sccm, a pressure 4.0 Pa, and an output 150 W.

After that, the separation process of the resist was performed by the water-based separation solution (TST-AQ3: made by Tokyo Ohka Kogyo Co., Ltd.) containing organic amines described above. By using isopropylalcohol, the residual separation solution was removed, and after that, water cleaning and drying process were performed. For each sample in which the separation process of this resist was completed, by using an ITO target (composition: In₂O₃—10 wt % SnO₂), a transparent electrode layer of the ITO was formed inside the contact hole and its periphery. The formation of the transparent electrode layer was performed by the sputtering (a substrate temperature 70° C., an input power 1.8 Watt/cm², an argon gas flow rate 80 sccm, an oxygen flow rate 0.7 sccm, and a pressure 0.37 Pa), and the ITO film of 1000 Å in thickness was formed.

This ITO film surface was covered with a resist (TFR-970: made by Tokyo Ohka Kogyo Co., Ltd.), and was subjected to an exposure process by disposing a pattern film, and was subjected to a development process by a TMAH developing solution, and the formation of a circuit of 10 μm in width was performed by an oxalic acid based mixed acid etching solution (ITO05N: made by Kanto Chemical Co. Inc). After forming the ITO film circuit, the resist was removed by the water-based separation solution (TST-AQ3: made by Tokyo Ohka Kogyo Co., Ltd.) containing an organic amines.

By using each test sample obtained by the fabrication method as described above, the adhesion resistance value was measured. The measurement method of this adhesion resistance value was such that the measurement of the resistance value was performed after the element of the test sample was subjected to an annealing process in the atmosphere of 250° C. for 30 minutes based on a four-terminal method as shown in FIG. 1. In this four-terminal method, 100 μA was conducted from the terminal portion of the test sample after heating process, and its resistance was measured. By the obtained adhesion resistance value, the ITO adhesion characteristic was estimated by the following four levels. The test sample in which the adhesion resistance value is 10Ω or less was estimated as ⊚, the sample in which the resistance value is 10 to 50Ω was estimated as ◯, the sample in which the resistance value is 50 to 200Ω was estimated as Δ, and the sample in which the value is 200Ω or more was estimated as ×.

Further, with respect to each Al based alloy film estimated in the present example, the measurement of the etching rate was performed, respectively. The measurement method of the etching rate was such that, first, on the glass substrate (#1737, a non-polished non-alkali glass of 0.7 mm in thickness: made by Corning Incorporated), a deposition of 2000 Å was performed on the same conditions as the deposition conditions of the above described Al based alloy film. The glass substrate on which the Al based alloy film was deposited was cut by a glass cutter into the shape of a long strip of approximately 1 cm in width and approximately 2.5 cm in length. Half of the film surface side of the sample cut into the shape of a long strip was covered by a masking tape, and was dipped into the developing solution in that state, and the time until the Al based alloy film not masked was completely disappeared was measured. From the film thickness of each sample pre-measured and the dissolution completion time of the film, the etching rate was calculated. Further, the measurement of the film thickness was performed such that the glass substrate deposited with the Al based alloy film was cut into the shape of a long strip approximately 1.5 cm in width and approximately 3 cm in length by a glass cutter, and an approximately half of the long strip was masked by an acid proof tape, and was dipped into aluminum mixed acid etchant (32° C. for ten minutes) in that state, and the Al based alloy film was sufficiently etched. After that, the acid proof tape was removed, and after an alcohol cleaning and a drying process, a step portion of the long strip surface was measured by a stylus profile meter (P-15: made by KLA Tencor Corporation), and the film thickness was measured. Incidentally, the developing solution was a developing solution of 2.38 wt % in TMAH density and the solution temperature was taken as 23° C. Table 1 shows the measurement result of the etching rate also.

TABLE 1

| | | Side | | |
|---|---|---|---|---|
| | Etching | etching | Circuit | ITO |
| | rate | character- | finishing | adhesion |
| Composition | (Å/sec) | istics | state | property |
| Al | 3.1 | X | None | X |
| Al-2 at % Nd | 1.9 | X | Heavy | X |
| Al-2 at % Ti | 0.9 | X | Heavy | X |
| Al-2 at % Y | 1.5 | X | Few | X |
| Al-2 at % Fe | 8.8 | ◯ | Moderate | Δ |
| Al-2 at % Co | 5.3 | ◯ | Moderate | ◯ |
| Al-2 at % Cu | 9.0 | ◯ | Moderate | X |
| Al-0.05 at % Ni | 4.2 | X | None | X |
| Al-0.1 at % Ni | 6.2 | ◯ | None | X |
| Al-0.5 at % Ni | 15.2 | ◯ | None | Δ |
| Al-1.0 at % Ni | 18.0 | ◯ | None | ◯ |
| Al-2.0 at % Ni | 20.2 | ⊚ | None | ⊚ |
| Al-3.0 at % Ni | 22.2 | ⊚ | None | ⊚ |
| Al-4.0 at % Ni | 24.8 | ⊚ | None | ⊚ |
| Al-5.0 at % Ni | 27.9 | ⊚ | Few | ⊚ |
| Al-6.0 at % Ni | 28.5 | ◯ | Few | ⊚ |
| Al-7.0 at % Ni | 30.2 | ◯ | None | ⊚ |
| Al-8.0 at % Ni | 32.5 | ◯ | Few | ⊚ |
| Al-9.0 at % Ni | 33.8 | ◯ | Few | ⊚ |
| Al-10.0 at % Ni | 35.1 | ◯ | Few | ⊚ |
| Al-11.0 at % Ni | 37.9 | ◯ | Moderate | ⊚ |
| Al-12.0 at % Ni | 40.6 | X | Heavy | ⊚ |
| Al-3.0 at % Ni-0.3 at % B | 21.7 | ⊚ | Few | ⊚ |
| Al-3.0 at % Ni-0.3 at % Y | 20.3 | ⊚ | Few | ⊚ |
| Al-3.0 at % Ni-0.3 at % C | 22.9 | ⊚ | None | ⊚ |
| Al-3.0 at % Ni-0.7 at % La | 24.0 | ◯ | Moderate | Δ |
| Al-3.0 at % Ni-1.0 at % Nd | 16.5 | ⊚ | Moderate | ◯ |

(TMAH solution temperature: 23° C.)

Further, the result of the development/etching process performed by the developing solution (solution temperature: 30° C.) of 2.38 wt % in TMAH density is shown in Table 2. Further, the etching rate was also measured at the solution temperature 30° C. Other deposition conditions, the forming condition of the wiring circuit, the method of estimating the characteristics are the same as the case of Table 1.

TABLE 2

| | | Side | | |
|---|---|---|---|---|
| | Etching | etching | Circuit | ITO |
| | rate | character- | finishing | adhesion |
| Composition | (Å/sec) | istics | state | property |
| Al | 6.9 | ◯ | None | X |
| Al-2 at % Nd | 3.5 | X | Heavy | X |
| Al-2 at % Ti | 2.5 | X | Heavy | X |
| Al-2 at % Y | 3.7 | Δ | Few | X |
| Al-2 at % Fe | 15.2 | ◯ | Few | Δ |
| Al-2 at % Co | 11.4 | ◯ | Few | ◯ |
| Al-2 at % Cu | 19.8 | ⊚ | None | X |
| Al-0.05 at % Ni | 7.8 | ◯ | None | X |
| Al-0.1 at % Ni | 13.1 | ◯ | None | X |
| Al-0.5 at % Ni | 20.4 | ⊚ | None | Δ |
| Al-1.0 at % Ni | 26.3 | ⊚ | None | ◯ |
| Al-2.0 at % Ni | 28.1 | ⊚ | None | ⊚ |
| Al-3.0 at % Ni | 30.7 | ⊚ | None | ⊚ |
| Al-4.0 at % Ni | 32.8 | ⊚ | None | ⊚ |
| Al-5.0 at % Ni | 34.2 | ⊚ | None | ⊚ |
| Al-6.0 at % Ni | 36.9 | ◯ | Few | ⊚ |
| Al-7.0 at % Ni | 37.3 | ◯ | None | ⊚ |
| Al-8.0 at % Ni | 38.5 | ◯ | None | ⊚ |
| Al-9.0 at % Ni | 41.8 | X | None | ⊚ |
| Al-10.0 at % Ni | 43.1 | X | None | ⊚ |
| Al-11.0 at % Ni | 46.9 | X | Few | ⊚ |
| Al-12.0 at % Ni | 47.6 | X | Moderate | ⊚ |
| Al-3.0 at % Ni-0.3 at % B | 29.1 | ⊚ | None | ⊚ |
| Al-3.0 at % Ni-0.3 at % Y | 27.8 | ⊚ | Few | ⊚ |
| Al-3.0 at % Ni-0.3 at % C | 30.9 | ⊚ | None | ⊚ |
| Al-3.0 at % Ni-0.7 at % La | 32.0 | ⊚ | Moderate | Δ |
| Al-3.0 at % Ni-1.0 at % Nd | 25.6 | ◯ | Moderate | ◯ |

(TMAH solution temperature: 30° C.)

From the result of the side etching characteristics of Tables 1 and 2, it was found that the formation of the Al based alloy wiring circuit can be satisfactorily performed when the etching rate is 5 to 40 Å/sec. Particularly, it was confirmed that the formation of the wiring circuit by the Al based alloy containing Ni is good. Further, regardless of the etching rate, cloudiness was occasionally confirmed on the glass substrate. When the solution temperature of the TMAH solution reaches a high temperature, the etching rate of the Al based alloy film changed sharply. Incidentally, when the nickel content exceeds 8 at %, though the glass substrates generated with cloudiness and not generated with cloudiness co-exist, when the nickel content is 8 at % or less, it is empirically confirmed that no generation of the cloudiness exists.

### EXAMPLE 2

In this example 2, with respect to three types of the Al based alloy of Al-8.0 at Ni, Al-9.0 at Ni, and Al-10.0 at Ni in the above described example 1, the result of changing the separation solution of the resist and performing the circuit formation will be described. The deposition conditions and the circuit forming conditions are basically the same as the case of the above described Example 1, and as a resist separation solution, a non-water-based amines separation solution 1 (ST106: made by Tokyo Ohka Kogyo Co., Ltd.) comprising monoethanolamine and DMSO (dimethylsulfoxide), and a non-water-based solvent separation solution 2 which is a polar solvent comprising DMSO (dimethylsulfoxide: 100 wt %) were used. Further, the developing solution was 2.38 wt % in TMAH density, and the solution temperature was taken as 23° C. The estimation in this example 2 confirmed a cloudy state of the glass substrate surface after the development/etching process in a finishing state of the wiring circuit by the optical microscope, and a cloudy state of the glass substrate surface after the resist separation process. The result is shown in Table 3.

TABLE 3

| | Circuit finishing state | | | |
|---|---|---|---|---|
| | | TST-AQ3 water- | ST106 non-water- | DMSO non-water- |
| | After | based amines | based amines | based solvent |
| | development/ | separation | separation | separation |
| Composition | etching process | solution 1 | solution 1 | solution 2 |
| Al-8.0 at % Ni | Few | None | None | Few |
| Al-9.0 at % Ni | Few | None | None | Few |
| Al-10.0 at % Ni | Few | None | None | Few |

From the result of Table 3, in the non-water-based solvent separation solution 2, it was confirmed that the cloudiness on the glass substrate remains. In contrast to this, in the water-based or non-water-based separation solution containing the organic amine, it was found that the cloudiness on the glass surface is dissolved.

1. A method of forming an aluminum based alloy wiring circuit comprising providing an aluminum based alloy film coated with a resist layer, exposing the resist layer to a pattern of a wiring circuit, developing the resist with a development process and etching the aluminum based alloy film in an etching process wherein the development process of the resist layer and the etching process of the aluminum based alloy film are simultaneously performed with a developing solution for the aluminum based alloy film coated with the resist layer.

2. The method of forming the aluminum based alloy wiring circuit according to claim 1, wherein the aluminum based alloy film is etched at a 5 Å/sec to 40 Å/sec etching rate by the developing solution.

3. The method of forming the aluminum based alloy wiring circuit according to claim 1 wherein the aluminum based alloy contains nickel of 0.1 at % to 8.0 at %.

4. The method of forming the aluminum based alloy wiring circuit according to claim 1 wherein the aluminum based alloy contains boron of 0.05 at % to 1.0 at %.

5. The method of forming the aluminum based alloy wiring circuit according to claim 3, wherein the aluminum based alloy contains boron of 0.05 at % to 1.0 at %.

6. The method of forming the aluminum based alloy wiring circuit according to claim 1 wherein a developing solution is a solution containing tetramethylammonium hydroxide.

7. The method of forming the aluminum based alloy wiring circuit according to claim 3, wherein a developing solution is a solution containing tetramethylammonium hydroxide.

8. The method of forming the aluminum based alloy wiring circuit according to claim 4, wherein a developing solution is a solution containing tetramethylammonium hydroxide.

9. The method of forming the aluminum based alloy wiring circuit according to claim 5, wherein a developing solution is a solution containing tetramethylammonium hydroxide.

10. A method of forming an element structure of a display device having a direct adhesion with the aluminum based alloy wiring circuit and a transparent electrode, and including the following processes A to E;
A: a deposition process of forming an aluminum based alloy film;
B: an exposure process of disposing a resist layer on the aluminum based alloy film and performing an exposure process of a wiring pattern;
C: a process of forming an aluminum based alloy wiring circuit, which simultaneously performs the development process of the wiring circuit pattern of the resist layer with a developing solution and an etching process to form the aluminum based alloy wiring circuit;
D: a separation process of removing the resist layer on the aluminum based alloy wiring circuit; and
E: an adhering process of directly adhering the aluminum based alloy wiring circuit and the transparent electrode.

11. The method of forming the element structure of display device according to claim 10, further including the following processes F to G:
F: a contact hole forming process of forming an insulating layer on the aluminum based alloy wiring circuit and forming a contact hole on the insulating layer, and
G: an element structure forming process of forming a transparent electrode on the contact hole and directly adhering the aluminum based wiring circuit and the transparent electrode inside the contact hole.

12. The method of forming an element structure of display device according to claim 10 wherein the transparent electrode is a transparent conductive film containing any of In, Sn, and Zn.

13. A display device element, which is formed by the method of forming the element structure of display device according to claim 10.

14. A display device element, which is formed by the method of forming the element structure of display device according to claim 12.

15. An aluminum based alloy target used in the deposition process in the method of forming the element structure of display device according to claim 10, which is an aluminum based alloy target containing nickel of 0.1 at % to 8.0 at %.

16. An aluminum based alloy target used in the deposition process in the method of forming the element structure of display device according to claim 12 which is an aluminum based alloy target containing nickel of 0.1 at % to 8.0 at %.

17. The method of forming the aluminum based alloy wiring circuit according to claim 2 wherein the aluminum based alloy contains nickel of 0.1 at % to 8.0 at %.

18. The method of forming the aluminum based alloy wiring circuit according to claim 2 wherein the aluminum based alloy contains boron of 0.05 at % to 1.0 at %.

19. The method of forming the aluminum based alloy wiring circuit according to claim 17, wherein the aluminum based alloy contains boron of 0.05 at % to 1.0 at %.

20. The method of forming the aluminum based alloy wiring circuit according to claim 2 wherein a developing solution is a solution containing tetramethylammonium hydroxide.
